(19) United States
(12) Patent Application Publication
(10) Pub. No.: US 2023/0275069 A1
(43) Pub. Date: Aug. 31, 2023

(54) SEMICONDUCTOR DEVICE AND CIRCUIT DEVICE

(71) Applicant: RENESAS ELECTRONICS CORPORATION, Tokyo (JP)

(72) Inventors: Hiroshi YANAGIGAWA, Tokyo (JP); Yasutaka NAKASHIBA, Tokyo (JP); Toshiyuki HATA, Tokyo (JP)

(21) Appl. No.: 18/059,583

(22) Filed: Nov. 29, 2022

(30) Foreign Application Priority Data
Feb. 3, 2022 (JP) 2022-015405

(51) Int. Cl. H01L 25/065; H01L 23/495; H01L 23/498; H01L 23/482

(52) U.S. Cl. CPC H01L 25/0657; H01L 23/4828; H01L 23/49572; H01L 23/49844

(57) ABSTRACT

A semiconductor device includes a first semiconductor chip including a first MOSFET of n-type and a first parasitic diode and a second semiconductor chip including a second MOSFET of n-type and a second parasitic diode. A first source electrode and a first gate wiring are formed on a first front surface of the first semiconductor chip, and a first drain electrode is formed on a first back surface of the first semiconductor chip. A second source electrode and a second gate wiring are formed on a second front surface of the second semiconductor chip, and a second drain electrode is formed on a second back surface of the second semiconductor chip. The first back surface and the second back surface are faced to each other such that the first drain electrode and the second drain electrode are in contact with each other via a conductive tape.

### CROSS-REFERENCE TO RELATED APPLICATIONS

The disclosure of Japanese Patent Application No. 2022-015405 filed on Feb. 3, 2022 including the specification, drawings and abstract is incorporated herein by reference in its entirety.

### BACKGROUND

The present invention relates to a semiconductor device and a circuit device, and particularly relates to a semiconductor device having a MOSFET of n-type and a circuit device using the semiconductor device.

Automobiles are equipped with many electrical devices that require electric power, such as headlights and power windows. Conventionally, relays have been used as switches for supplying or cutting off power from a battery to these electrical devices. In recent years, semiconductor devices including n-type power MOSFETs (Metal Oxide Semiconductor Field Effect Transistors) have been used instead of relays.

At the time of maintenance of the battery, in some cases, cables connected to the battery are detached, and the cables are connected again to the battery after the maintenance is finished. At that time, a trouble that the cables are connected in reverse with respect to a positive electrode and a negative electrode of the battery occurs in some cases. In the switch using a relay, if the switch is in the OFF state, no current flows even in the case of the reverse connection.

However, in the switch using a semiconductor device, even if the power MOSFET is in the OFF state, current flows through the parasitic diode formed in the power MOSFET. In order to prevent such reverse current flow, a p-type power MOSFET is connected in series between the drain of the n-type power MOSFET and the positive electrode of the battery.

In that case, as a form of a semiconductor device (semiconductor module), a technique of preparing a semiconductor chip having an n-type power MOSFET and a semiconductor chip having a p-type power MOSFET as separate packages is conceivable (first case). Alternatively, a technique of placing a semiconductor chip having an n-type power MOSFET and a semiconductor chip having a p-type power MOSFET flatly and preparing these chips as one package is conceivable (second case). However, the first case has a problem that the mounting area becomes large, and the second case has a problem that the package area becomes large.

There are disclosed techniques listed below.
[Patent Document 1] Japanese Unexamined Patent Application Publication No. 2016-207716
[Patent Document 2] Japanese Unexamined Patent Application Publication No. 2012-243930

In Patent Document 1, an n-type power MOSFET connected in series with its source and drain directed in reverse is used instead of a p-type power MOSFET in order to prevent reverse current flow. A semiconductor device in which two n-type power MOSFETs are formed on the same semiconductor substrate and are prepared as one package (third case) is disclosed. Namely, the source of one n-type power MOSFET is connected to the positive terminal of the battery, the drain of one n-type power MOSFET is connected to the drain of the other n-type power MOSFET, and the source of the other n-type power MOSFET is connected to the negative terminal of the battery.

In addition, Patent Document 2 discloses a semiconductor device in which a power MOSFET of n-type of trench gate type and a MOSFET of n-type of planar type are formed on the same semiconductor substrate.

### SUMMARY

In the semiconductor device of Patent Document 1 (third case), the mounting area and the package area can be reduced as compared with the first case and the second case.

However, the drains of the two n-type power MOSFETs connected to each other are electrically connected via the n-type drift region in the semiconductor substrate, the drain electrode formed on the side of the back surface of the semiconductor substrate, and the lead frame formed below the drain electrode. Namely, since the resistance component between the two n-type power MOSFETs in the horizontal direction becomes large, there is a problem that it is difficult to improve the performance of the semiconductor device. Therefore, when a semiconductor device is used for a switch, there is a problem that it is difficult to reduce the loss of the switch.

The main objects of this application are to reduce the mounting area and the package area as compared with the first case and the second case and to improve the performance of a semiconductor device by reducing the resistance component as compared with the third case. In this way, the loss of a circuit device using a semiconductor device as a switch is reduced.

The other problems and novel features will be apparent from the description of this specification and the accompanying drawings.

An outline of the typical embodiment disclosed in this application will be briefly described as follows.

A semiconductor device according to an embodiment includes a first semiconductor chip including a first MOSFET of n-type and a first parasitic diode formed in the first MOSFET and a second semiconductor chip including a second MOSFET of n-type and a second parasitic diode formed in the second MOSFET. Here, a first source electrode and a first gate wiring are formed on a front surface of the first semiconductor chip, a first drain electrode is formed on a back surface of the first semiconductor chip, a first anode of the first parasitic diode is coupled to the first source electrode and a first cathode of the first parasitic diode is coupled to the first drain electrode, a second source electrode and a second gate wiring are formed on a front surface of the second semiconductor chip, a second drain electrode is formed on a back surface of the second semiconductor chip, a second anode of the second parasitic diode is coupled to the second source electrode and a second cathode of the second parasitic diode is coupled to the second drain electrode, and the back surface of the first semiconductor chip and the back surface of the second semiconductor chip are faced to each other such that the first drain electrode and the second drain electrode are in contact with each other via a conductive member.

According to the embodiment, it is possible to improve the performance of a semiconductor device. Also, it is possible to reduce the loss of a circuit device using a semiconductor device as a switch.

### BRIEF DESCRIPTION OF THE DRAWINGS

FIG. 1 is an equivalent circuit diagram showing a circuit device using a semiconductor device according to the first embodiment.

FIG. 2 is a plan view showing one semiconductor chip in the first embodiment.

FIG. 3 is a plan view showing the other semiconductor chip in the first embodiment.

FIG. 4 is a cross-sectional view showing two MOSFETs and two parasitic diodes formed in the two semiconductor chips in the first embodiment.

FIG. 5 is a plan view showing the semiconductor device according to the first embodiment.

FIG. 6 is a plan view showing the semiconductor device according to the first embodiment.

FIG. 7 is a cross-sectional view showing the semiconductor device according to the first embodiment.

FIG. 8 is a cross-sectional view showing the semiconductor device according to the first embodiment.

FIG. 9 is a cross-sectional view showing the semiconductor device according to the first embodiment.

FIG. 10 is a cross-sectional view showing the semiconductor device according to the first embodiment.

FIG. 11 is a plan view showing a semiconductor device according to the studied example.

FIG. 12 is a cross-sectional view showing the semiconductor device according to the studied example.

FIG. 13 is a table showing the comparison between the resistance values in the first embodiment and the resistance values in the studied example.

FIG. 14 is a cross-sectional view showing a semiconductor device according to the second embodiment.

FIG. 15 is a plan view showing the other semiconductor chip in the third embodiment.

FIG. 16 is a cross-sectional view showing MOSFETs constituting a control circuit in the third embodiment.

### DETAILED DESCRIPTION

Hereinafter, embodiments will be described in detail with reference to drawings. In all the drawings for describing the embodiments, the members having the same function are denoted by the same reference characters and the repetitive description thereof will be omitted. Also, in the following embodiments, the description of the same or similar components is not repeated in principle unless particularly required.

### First Embodiment

### Circuit Device Using Semiconductor Device

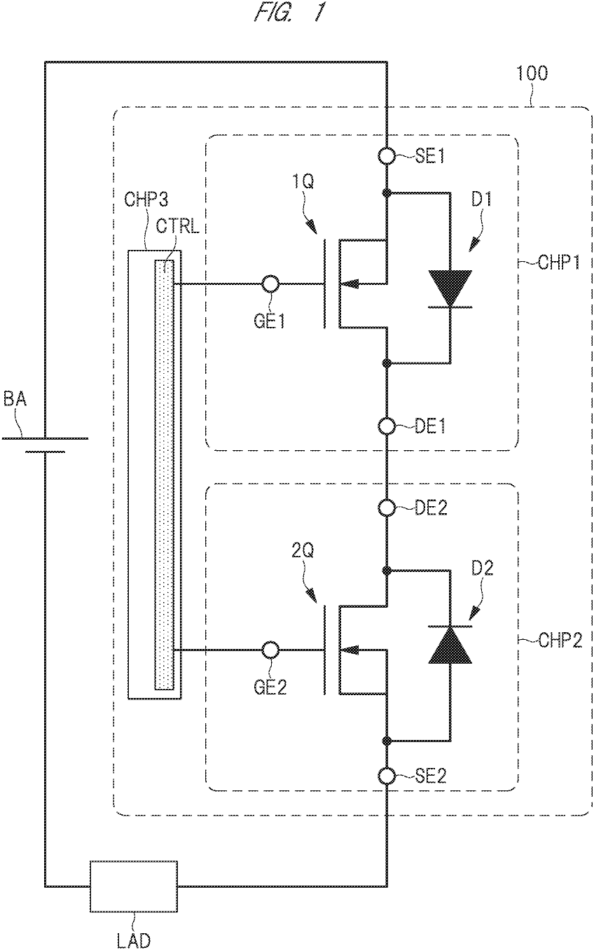

FIG. 1 shows a circuit device using a semiconductor device 100 according to the first embodiment as a switch. The semiconductor device 100 is a semiconductor module and includes a semiconductor chip CHP1 having a MOSFET 1Q of n-type and a parasitic diode D1 and a semiconductor chip CHP2 having a MOSFET 2Q of n-type and a parasitic diode D2. Also, the semiconductor device 100 may include a semiconductor chip CHP3 having a control circuit CTRL.

The circuit device of FIG. 1 includes the semiconductor device 100 used as a switch, a battery BA, and a load LAD. The load LAD is, for example, an electrical device mounted on an automobile, such as a headlamp or a power window.

A source electrode SE1 of the MOSFET 1Q is electrically connected to a positive electrode of the battery BA. A drain electrode DE1 of the MOSFET 1Q is electrically connected to a drain electrode DE2 of the MOSFET 2Q. A source electrode SE2 of the MOSFET 2Q is electrically connected to a negative electrode of the battery BA via the load LAD. A gate electrode GE1 of the MOSFET 1Q and a gate electrode GE2 of the MOSFET 2Q are electrically connected to the control circuit CTRL.

Note that the control circuit CTRL has a function of supplying a gate potential to the gate electrodes GE1 and GE2 in order to switch the ON state and the OFF state of each of the MOSFETs 1Q and 2Q. Further, the control circuit CTRL may include a booster circuit, an overheat shutdown control circuit, an overcurrent limiter circuit, a monitor circuit that detects current and voltage, and others as circuits having other functions.

The parasitic diode D1 is formed in the MOSFET 1Q. An anode of the parasitic diode D1 is coupled to the source electrode SE1 as shown in FIG. 1. Also, a cathode of the parasitic diode D1 is coupled to the drain electrode DE1 as shown in FIG. 1.

The parasitic diode D2 is formed in the MOSFET 2Q. An anode of the parasitic diode D2 is coupled to the source electrode SE2 as shown in FIG. 1. Also, a cathode of the parasitic diode D2 is coupled to the drain electrode DE2 as shown in FIG. 1.

The MOSFET 2Q is a device for performing a switching operation (ON operation and OFF operation) for supplying power to the load LAD as necessary when the battery BA is properly connected to the semiconductor device 100. The MOSFET 1Q is a device for preventing reverse current flow when the battery BA is reversely connected to the semiconductor device 100.

The circuit operation when the battery BA is properly connected to the semiconductor device 100 will be described. First, the case where power is supplied from the battery BA to the load LAD will be described. The MOSFETs 1Q and 2Q are turned on by supplying a gate potential higher than the threshold voltage of the MOSFETs 1Q and 2Q from the control circuit CTRL to the gate electrodes GE1 and GE2. Consequently, current flows from the battery BA to the load LAD.

The case of cutting off the power to the load LAD will be described. The MOSFETs 1Q and 2Q are turned off by supplying, for example, a ground potential (GND) from the control circuit CTRL to the gate electrodes GE1 and GE2. Here, even if the MOSFET 1Q is in the OFF state, a current flows through the parasitic diode D1, and the potential between the drain electrode DE1 and the drain electrode DE2 increases. However, no current flows through the parasitic diode D2. Accordingly, no current flows from the battery BA to the load LAD.

Next, the circuit operation when the battery BA is reversely connected to the semiconductor device 100 will be described. The MOSFETs 1Q and 2Q are turned off. Here, even if the MOSFET 2Q is in the OFF state, a current flows through the parasitic diode D2, and the potential between the drain electrode DE1 and the drain electrode DE2 increases. However, no current flows through the parasitic diode D1. In this way, it is possible to prevent the current flow from the battery BA to the load LAD.

### Structure of MOSFET and Parasitic Diode

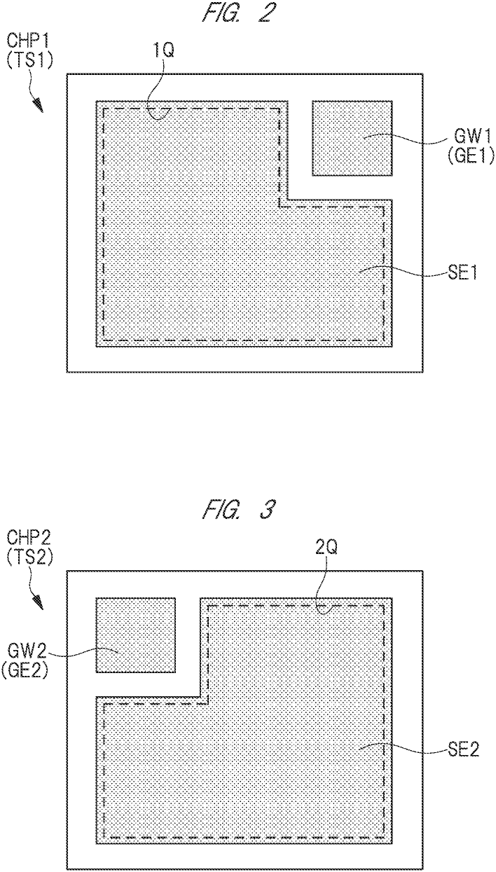

The semiconductor chip CHP1 has a front surface TS1 and a back surface BS1, and the semiconductor chip CHP2 has a front surface TS2 and a back surface BS2. FIG. 2 is a plan view of the semiconductor chip CHP1 viewed from the side of the front surface TS1. FIG. 3 is a plan view of the semiconductor chip CHP2 viewed from the side of the front surface TS2. Note that the planar area of the semiconductor chip CHP1 is substantially the same as the planar area of the semiconductor chip CHP2.

As shown in FIG. 2, the source electrode SE1 and a gate wiring GW1 are formed on the front surface TS1 of the semiconductor chip CHP1. Most of the semiconductor chip CHP1 is covered with the source electrode SE1, and the MOSFET 1Q is mainly formed below the source electrode SE1. Also, the gate electrode GE1 of the MOSFET 1Q is electrically connected to the gate wiring GW1.

As shown in FIG. 3, the source electrode SE2 and a gate wiring GW2 are formed on the front surface TS2 of the semiconductor chip CHP2. Most of the semiconductor chip CHP2 is covered with the source electrode SE2, and the MOSFET 2Q is mainly formed below the source electrode SE2. Also, the gate electrode GE2 of the MOSFET 2Q is electrically connected to the gate wiring GW2.

External connection members such as bonding wires or clips (copper plates) are connected onto the source electrodes SE1 and SE2 and the gate wirings GW1 and GW2, so that the semiconductor chips CHP1 and CHP2 are electrically connected to other chips, a wiring board, or the like.

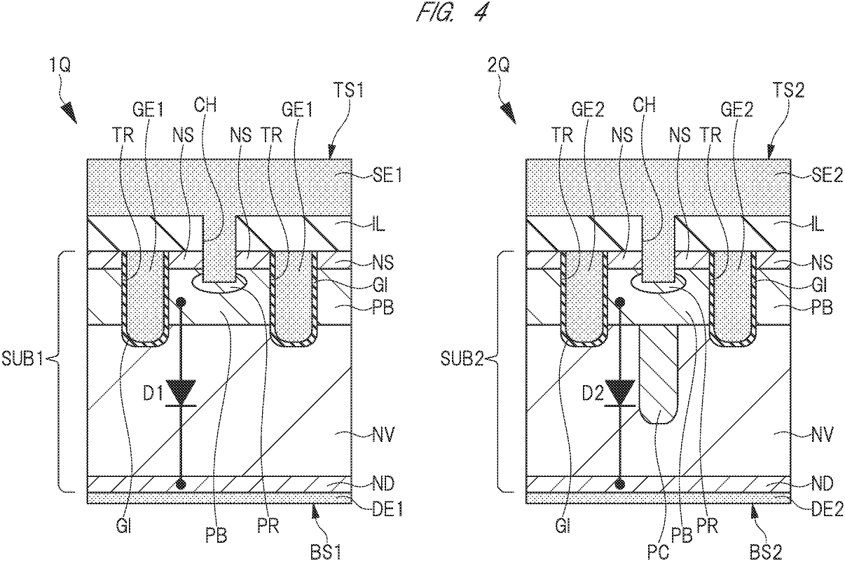

Structures of the MOSFET 1Q, the parasitic diode D1, the MOSFET 2Q, and the parasitic diode D2 will be described below with reference to FIG. 4. Note that a plurality of MOSFETs is actually formed in the semiconductor chips CHP1 and CHP2, and they are connected in parallel. Therefore, in terms of an equivalent circuit, the plurality of MOSFETs can be regarded as one MOSFET. In other words, the MOSFETs 1Q and 2Q described in this application are each equivalent to the plurality of MOSFETs connected in parallel that are presented as one MOSFET.

First, the structures of the MOSFET 1Q and the parasitic diode D1 will be described.

A semiconductor substrate SUB1 has a front surface and a back surface, and has a low-concentration n-type drift region NV. Here, the semiconductor substrate SUB1 is an n-type silicon substrate, and the semiconductor substrate SUB1 itself forms the drift region NV. Note that the drift region NV may be a stacked body of an n-type silicon substrate and a semiconductor layer grown on the silicon substrate by the epitaxial growth method while introducing phosphorus (P). In this application, the description is given assuming that such a stacked body is also the semiconductor substrate SUB1.

A p-type body region PB is formed in the semiconductor substrate SUB1 on a side of the front surface of the semiconductor substrate SUB1. An n-type source region NS is formed in the body region PB. The source region NS has an impurity concentration higher than that of the drift region NV.

Trenches TR are formed in the semiconductor substrate SUB1 on a side of the front surface of the semiconductor substrate SUB1. The bottom portion of each trench TR reaches a position deeper than the body region PB. A gate insulating film GI is formed inside each trench TR. A gate electrode GE1 is formed on the gate insulating film GI so as to fill the inside of each trench TR. Namely, the MOSFET 1Q has a trench gate structure. The gate insulating film GI is, for example, a silicon oxide film, and the gate electrode GE1 is, for example, an n-type polycrystalline silicon film.

An interlayer insulating film IL is formed on the front surface of the semiconductor substrate SUB1 so as to cover the gate electrodes GE1. The interlayer insulating film IL is, for example, a silicon oxide film. A hole CH is formed in the interlayer insulating film IL. The hole CH penetrates the interlayer insulating film IL and the source region NS such that the bottom portion thereof is located in the body region PB. Also, at the bottom portion of the hole CH, a p-type high-concentration region PR is formed in the body region PB. The high-concentration region PR has an impurity concentration higher than that of the body region PB.

The source electrode SE1 is formed on the interlayer insulating film IL so as to fill the inside of the hole CH. The source electrode SE1 is electrically connected to the source region NS, the body region PB, and the high-concentration region PR, and supplies the source potential thereto. Although not shown here, the gate wiring GW1 is also formed on the interlayer insulating film IL. The plurality of gate electrodes GE1 is collectively connected to a gate lead-out portion in an outer peripheral portion of the semiconductor chip CHP1. A hole CH is formed also on the gate lead-out portion, and the gate wiring GW1 is buried inside the hole CH. Therefore, the gate wiring GW1 is electrically connected to the gate electrode GE1 and supplies a gate potential to the gate electrode GE1.

The source electrode SE1 and the gate wiring GW1 are composed of, for example, a barrier metal film and a conductive film formed on the barrier metal film. The barrier metal film is, for example, a titanium nitride film, and the conductive film is, for example, an aluminum film.

Note that the source electrode SE1 and the gate wiring GW1 may be composed of a plug layer filling the inside of the hole CH and a wiring portion formed on the interlayer insulating film IL. In this case, the wiring portion is the stacked film of a titanium nitride film and an aluminum film mentioned above, and the plug layer is a stacked film of a barrier metal film such as a titanium nitride film and a conductive film such as a tungsten film.

An n-type drain region ND is formed in the semiconductor substrate SUB1 on a side of the back surface of the semiconductor substrate SUB1. The drain region ND has an impurity concentration higher than that of the drift region NV. The drain electrode DE1 is formed on the back surface of the semiconductor substrate SUB1. The drain electrode DE1 is electrically connected to the drain region ND and the drift region NV, and supplies a drain potential to the drain region ND. The drain electrode DE1 is composed of a single-layer metal film such as an aluminum film, a titanium film, a nickel film, a gold film, or a silver film, or a stacked film in which these metal films are stacked as appropriate.

The parasitic diode D1 is composed of the body region PB and the semiconductor substrate SUB1 (drift region NV) and the drain region ND located below the body region PB. Namely, in the semiconductor chip CHP1, the parasitic diode D1 is a PN diode whose anode is the body region PB and whose cathode is the semiconductor substrate SUB1 and the drain region ND.

The structure of the MOSFET 2Q is basically the same as that of the MOSFET 1Q except that reference characters of a semiconductor substrate SUB2, a front surface TS2, a back surface BS2, the gate electrode GE2, the source electrode SE2, the gate wiring GW2, and the drain electrode DE2 are different. Therefore, details of the structure of the MOSFET 2Q will be omitted so as to avoid the redundant description.

The parasitic diode D2 is composed of the body region PB and the semiconductor substrate SUB2 (drift region NV) and the drain region ND located below the body region PB. Namely, in the semiconductor chip CHP2, the parasitic diode D2 is a PN diode whose anode is the body region PB and whose cathode is the semiconductor substrate SUB2 and the drain region ND.

A difference from the MOSFET 1Q is that the MOSFET 2Q has a column region PC of p-type formed in the semiconductor substrate SUB1 located below the body region PB. The column region PC has an impurity concentration higher than that of the body region PB. In the case of the MOSFET 2Q of n-type, by forming such a column region PC of p-type, the periphery of the column region PC can be depleted and the withstand voltage can be improved.

Here, since the column region PC is in contact with the body region PB, the source potential is supplied also to the column region PC of p-type. However, the column region PC may be physically separated from the body region PB and may have a floating structure.

The column region PC may be formed also in the MOSFET 1Q, but forming the column region PC causes the increase in the on-resistance. The MOSFET 2Q is a main device that serves as a switch in the circuit device of FIG. 1. Therefore, in order to ensure the reliability of the switch when the battery BA is connected, it is preferable that the column region PC is formed in the MOSFET 2Q. In order to quickly supply power to the load LAD, it is preferable that the MOSFET 1Q does not have the column region PC so as to reduce on-resistance.

On the other hand, if the column region PC is formed in both the MOSFET 1Q and the MOSFET 2Q or if the column region PC is not formed in the MOSFET 1Q and the MOSFET 2Q, the semiconductor chip CHP1 is the same semiconductor chip as the semiconductor chip CHP2. Therefore, in those cases, there is no need to develop, manufacture, and procure other semiconductor chips, so the labor involved in manufacturing the semiconductor device 100 can be simplified.

### Structure of Semiconductor Device

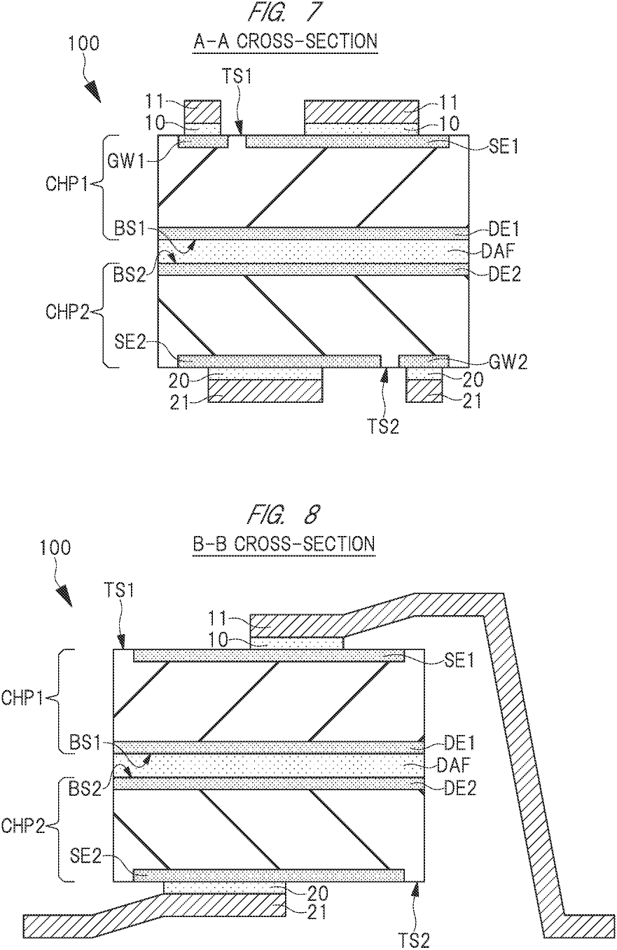

The structure of the semiconductor device 100 will be described below with reference to FIG. 5 to FIG. 10. FIG. 5 is a plan view showing the semiconductor device 100. FIG. 7 is a cross-sectional view taken along the line A-A in FIG. 5. FIG. 8 is a cross-sectional view taken along the line B-B in FIG. 5.

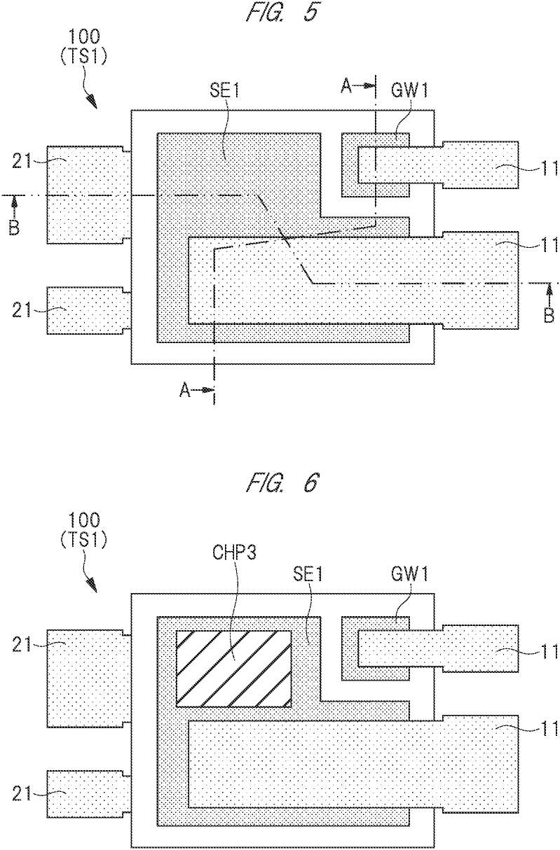

Note that FIG. 6 shows a state in which the semiconductor chip CHP3 including the control circuit CTRL is mounted on the semiconductor chip CHP1. The semiconductor chip CHP3 is provided on the source electrode SE1 via an insulating resin or the like. In FIG. 7 and FIG. 8, illustration of the semiconductor chip CHP3 is omitted for simplification of description.

As shown in FIG. 7 and FIG. 8, in the semiconductor device 100, the semiconductor chip CHP1 and the semiconductor chip CHP2 are stacked while inverting one of the semiconductor chip CHP1 and the semiconductor chip CHP2. Namely, the back surface BS1 of the semiconductor chip CHP1 and the back surface BS2 of the semiconductor chip CHP2 are faced to each other such that the drain electrode DE1 and the drain electrode DE2 are in contact with each other via a conductive member. In the first embodiment, the conductive member is a conductive tape DAF.

As shown in FIG. 5 to FIG. 8, the source electrode SE1 and the gate wiring GW1 are connected to an external connection member 11 via a conductive paste 10 on the side of the front surface TS1 of the semiconductor chip CHP1. Also, the source electrode SE2 and the gate wiring GW2 are connected to an external connection member 21 via a conductive paste 20 on the side of the front surface TS2 of the semiconductor chip CHP2. The conductive pastes 10 and 20 are, for example, silver pastes. The external connection members 11 and 21 are, for example, clips (copper plates) or bonding wires made of copper or aluminum. Here, the case where the external connection members 11 and 21 are clips is illustrated, and the clips are processed so as to bend toward the front surface TS2 of the semiconductor chip CHP2.

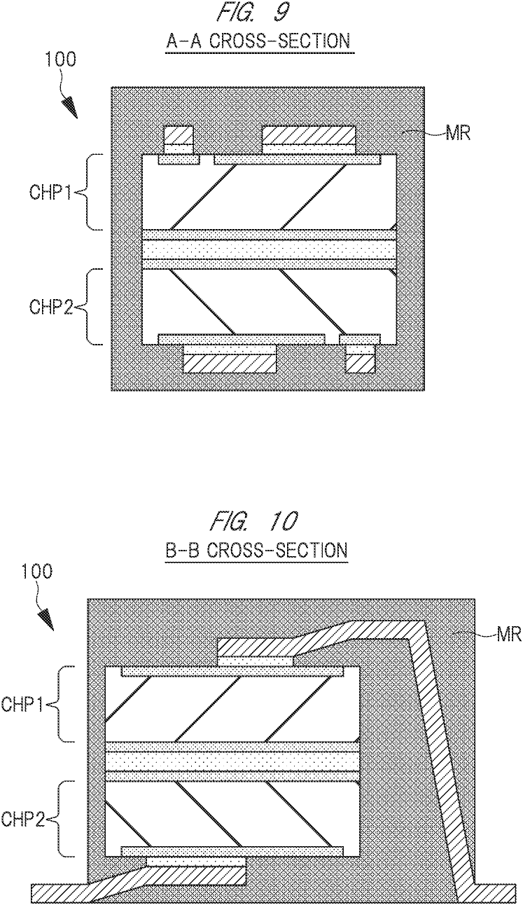

As shown in FIG. 9 and FIG. 10, the semiconductor chip CHP1, the semiconductor chip CHP2, the conductive tape DAF, and the external connection members 11 and 21 are sealed with a sealing resin MR. Parts of the external connection members 11 and 21 are exposed from the sealing resin MR. Therefore, the MOSFETs 1Q and 2Q can be electrically connected to other semiconductor chips, a wiring board, electronic devices, or the like via the exposed parts of the external connection members 11 and 21. Namely, the switch composed of the MOSFETs 1Q and 2Q can be electrically connected to the battery BA and the load LAD as shown in FIG. 1.

When the semiconductor chip CHP3 is mounted as shown in FIG. 6, the semiconductor chips CHP1 to CHP3 can be provided as one package by sealing the semiconductor chip CHP3 together with the semiconductor chips CHP1 and CHP2 with the sealing resin MR. Also, the semiconductor chip CHP3 may be packaged separately from the semiconductor chips CHP1 and CHP2.

Further, although the case where the semiconductor chip CHP2 is inverted upside down and the semiconductor chip CHP1 is arranged above the semiconductor chip CHP2 is illustrated here, it is also possible to invert the semiconductor chip CHP1 upside down and arrange the semiconductor chip CHP2 above the semiconductor chip CHP1.

### Comparison with Studied Example

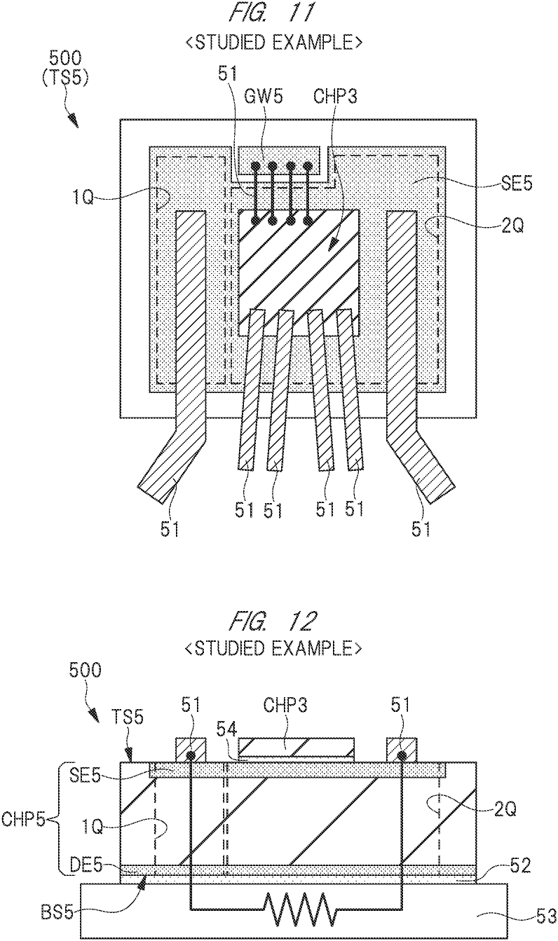

FIG. 11 and FIG. 12 show a semiconductor device 500 according to a studied example which the inventors of this application has studied for the case of packaging two MOSFETs of n-type disclosed in Patent Document 1 (third case).

As shown in FIG. 11 and FIG. 12, a semiconductor chip CHP5 of the studied example includes the MOSFET 1Q of n-type and the MOSFET 2Q of n-type formed on the same semiconductor substrate. A source electrode SE5 and a gate wiring GW5 are formed on a front surface TS5 of the semiconductor chip CHP5, and a drain electrode DE5 is formed on a back surface BS5 of the semiconductor chip CHP5. Note that, when the semiconductor device 500 according to the studied example is used as a switch, an equivalent circuit similar to that of the circuit device in FIG. 1 is formed.

The source electrode SE5 and the gate wiring GW5 are directly connected to external connection members 51. The drain electrode DE5 is connected to a lead frame 53 via a conductive paste 52. The semiconductor chip CHP3 including the control circuit CTRL is provided on the source electrode SE5 via an insulating resin 54 or the like.

In the studied example, the drains of the two MOSFETs 1Q and 2Q are electrically connected via the n-type drift region in the semiconductor substrate, the drain electrode DE5, and the lead frame 53. Accordingly, there is a problem that the resistance component between the two MOSFETs 1Q and 2Q in the horizontal direction becomes large, and it is thus difficult to reduce the loss of the switch. Therefore, there is a problem that it is difficult to improve the performance of the semiconductor device.

Also, since the MOSFETs 1Q and 2Q are formed on the same semiconductor substrate, the formation areas thereof are small. In particular, if priority is given to the MOSFET 2Q which is the main device, the formation area of the MOSFET 1Q tends to be small. Therefore, there is a problem that it is difficult to reduce the on-resistance of the MOSFETs 1Q and 2Q. In addition, since the installation area of the external connection members 51 cannot be increased, there is a problem that the resistance values associated with these members tend to increase.

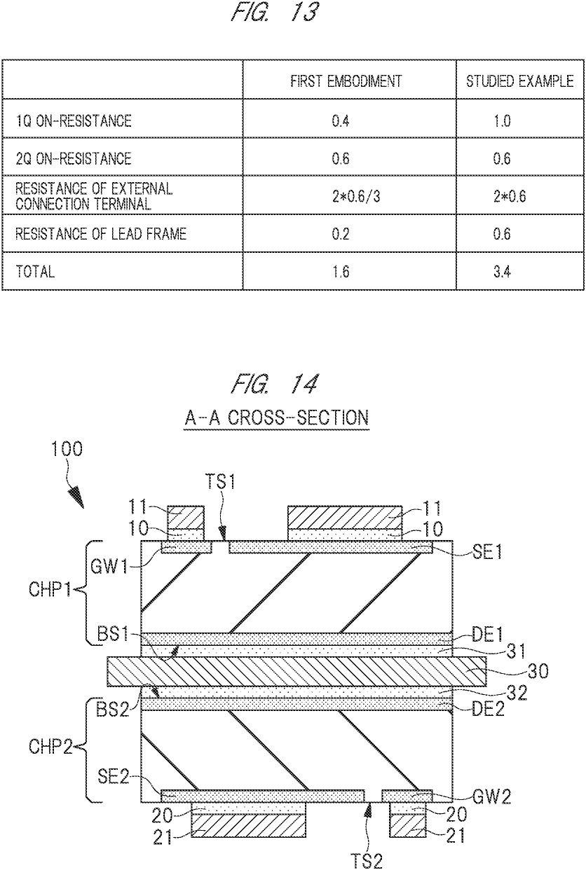

FIG. 13 is a table showing the comparison between the resistance values in the semiconductor device 100 according to the first embodiment and the resistance values in the semiconductor device 500 according to the studied example. Note that the numerical values in FIG. 13 are shown as relative values. Here, the above numerical values are calculated assuming that the formation area of the MOSFET 2Q in the first embodiment is approximately the same as the formation area of the MOSFET 2Q in the studied example.

In the first embodiment, since the semiconductor chip CHP1 including the MOSFET 1Q is separated from the semiconductor chip CHP2, the formation area of the MOSFET 1Q can be increased as compared with the studied example. Therefore, the on-resistance of the MOSFET 1Q can be reduced.

Further, in the first embodiment, since the external connection members 11 and 21 can be provided on the front surface TS1 of the semiconductor chip CHP1 and the front surface TS2 of the semiconductor chip CHP2, respectively, the installation areas of the external connection members increase and it becomes easy to reduce the resistance values associated with these members. Roughly speaking, in the first embodiment, it is possible to arrange the external connection members about three times as many as those in the studied example.

In addition, there are many resistance components in the horizontal direction such as the lead frame 53 in the studied example, but the drain electrode DE1 and the drain electrode DE2 are in contact with each other in the vertical direction via the conductive tape DAF in the first embodiment. Therefore, since the distance between the drain electrode DE1 and the drain electrode DE2 is short, the resistance component between the two MOSFETs 1Q and 2Q can be reduced.

As described above, according to the first embodiment, it is possible to realize the mounting area and the package area equal to or smaller than those of the studied example (third case) and to reduce the resistance component as compared with the studied example, and thus the performance of the semiconductor device 100 can be improved. Further, it is possible to reduce the loss of the circuit device using the semiconductor device 100 as a switch.

### Second Embodiment

A semiconductor device 100 according to the second embodiment will be described below with reference to FIG. 14. In the following, differences from the first embodiment will be mainly described, and descriptions of points overlapping with the first embodiment will be omitted.

In the first embodiment, the conductive tape DAF is used as the conductive member interposed between the drain electrode DE1 and the drain electrode DE2. As shown in FIG. 14, the conductive member of the second embodiment includes a lead frame 30, a conductive paste 31, and a conductive paste 32.

The lead frame 30 is provided between the drain electrode DE1 and the drain electrode DE2. The planar size of the lead frame 30 is larger than the planar sizes of the semiconductor chips CHP1 and CHP2 such that the semiconductor chips CHP1 and CHP2 can be stably installed.

The conductive paste 31 is provided between the drain electrode DE1 and the lead frame 30 and adheres to the drain electrode DE1 and the lead frame 30. The conductive paste 32 is provided between the drain electrode DE2 and the lead frame 30 and adheres to the drain electrode DE2 and the lead frame 30. For example, the conductive pastes 31 and 32 are silver pastes.

Between the drain electrode DE1 and the drain electrode DE2, the resistance value of the structure composed of the lead frame 30, the conductive paste 31, and the conductive paste 32 is smaller than the resistance value of the conductive tape DAF. Therefore, in the second embodiment, the performance of the semiconductor device 100 can be further improved as compared with the first embodiment. Also, it is possible to further reduce the loss in a circuit device using the semiconductor device 100 as a switch.

In addition, since the conductive pastes 31 and 32 have strong adhesion, the adhesion between the drain electrode DE1 and the drain electrode DE2 can be enhanced.

### Third Embodiment

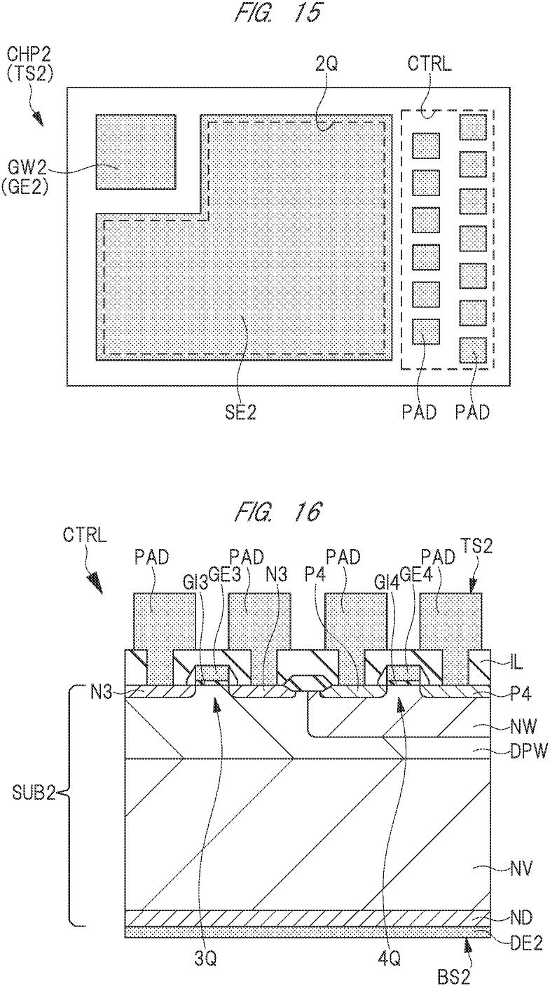

A semiconductor device 100 according to the third embodiment will be described below with reference to FIG. 15 and FIG. 16. In the following, differences from the first embodiment will be mainly described, and descriptions of points overlapping with the first embodiment will be omitted.

In the first embodiment, the control circuit CTRL is included in the semiconductor chip CHP3. As shown in FIG. 15, in the third embodiment, the control circuit CTRL is included in the semiconductor chip CHP2. Transistors constituting the control circuit CTRL are formed in a region of the semiconductor substrate SUB2 different from the region where the MOSFET 2Q is formed.

The transistors constituting the control circuit CTRL are, for example, a MOSFET 3Q of n-type and a MOSFET 4Q of p-type shown in FIG. 16. The MOSFETs 3Q and 4Q have a planar structure. A p-type well region DPW is formed in the semiconductor substrate SUB2 in the region where the MOSFETs 3Q and 4Q are formed, and the MOSFET 2Q is electrically separated from the MOSFETs 3Q and 4Q by the well region DPW.

The structure of the MOSFET 3Q will be described. A gate electrode GE3 is formed on the well region DPW via a gate insulating film GI3. An n-type diffusion region N3 is formed in the well region DPW. The diffusion region N3 constitutes a source region or a drain region of the MOSFET 3Q.

The structure of the MOSFET 4Q will be described. An n-type well region NW is formed in the well region DPW in which the MOSFET 4Q is formed. A gate electrode GE4 is formed on the well region NW via a gate insulating film GI4. A p-type diffusion region P4 is formed in the well region NW. The diffusion region P4 constitutes a source region or a drain region of the MOSFET 4Q.

The MOSFETs 3Q and 4Q are covered with the interlayer insulating film IL, and a plurality of pad electrodes PAD is formed on the interlayer insulating film IL. The plurality of pad electrodes PAD is electrically connected to the gate electrodes GE3 and GE4 and the diffusion regions N3 and P4. Note that the plurality of pad electrodes PAD is formed in the same manufacturing process as the source electrode SE2 and the gate wiring GW2, and are made of the same material as the source electrode SE2 and the gate wiring GW2.

There are multiple MOSFETs 3Q and 4Q formed respectively, and they constitute various circuits such as a CMOS inverter together with the plurality of pad electrodes PAD. Although not shown here, the MOSFETs 3Q and 4Q are electrically connected to other semiconductor chips, a wiring board, electronic devices, or the like via external connection members (bonding wires) connected to the plurality of pad electrodes PAD. Therefore, the MOSFETs 3Q and 4Q are electrically connected to the MOSFETs 1Q and 2Q.

By incorporating the control circuit CTRL in the semiconductor chip CHP2 in this manner, there is no need to prepare the semiconductor chip CHP3. Therefore, the manufacture of the semiconductor device 100 can be simplified. Note that it is also possible to incorporate the control circuit CTRL in the semiconductor chip CHP1 instead of the semiconductor chip CHP2.

Also, the technique disclosed in the third embodiment can be used in combination with the technique disclosed in the second embodiment as appropriate.

In the foregoing, the present invention has been specifically described based on the embodiments, but the present invention is not limited to the embodiments described above and can be modified in various ways within the scope not departing from the gist thereof.

For example, in the above embodiments, the case where the load LAD of the circuit device is an electrical device used in an automobile has been described, but the circuit device is not limited to the device used for automobiles, and the load LAD may be other electrical device used in other purposes except automobiles.

Further, in the above embodiments, the semiconductor substrates SUB1 and SUB2 are described as n-type silicon substrates. However, the material of the semiconductor substrates SUB1 and SUB2 is not limited to silicon, and the semiconductor substrates SUB1 and SUB2 may be n-type silicon carbide substrates (n-type SiC substrates).

Also, in the above embodiments, the MOSFETs 1Q and 2Q have a trench gate structure. However, the MOSFETs 1Q and 2Q may have a planar structure as long as the source electrodes SE1 and SE2 and the gate wirings GW1 and GW2 are provided on the side of the front surfaces TS1 and TS2 and the drain electrodes DE1 and DE2 are provided on the side of the back surfaces BS1 and BS2. Namely, the gate electrodes GE1 and GE2 may be formed on the semiconductor substrates SUB1 and SUB2 via the gate insulating film GI without forming the trenches TR.

What is claimed is:

1. A semiconductor device comprising:
a first semiconductor chip including a first MOSFET of n-type and a first parasitic diode formed in the first MOSFET; and
a second semiconductor chip including a second MOSFET of n-type and a second parasitic diode formed in the second MOSFET,
wherein a first source electrode and a first gate wiring are formed on a front surface of the first semiconductor chip,
wherein a first drain electrode is formed on a back surface of the first semiconductor chip,
wherein a first anode of the first parasitic diode is coupled to the first source electrode and a first cathode of the first parasitic diode is coupled to the first drain electrode,
wherein a second source electrode and a second gate wiring are formed on a front surface of the second semiconductor chip,
wherein a second drain electrode is formed on a back surface of the second semiconductor chip,
wherein a second anode of the second parasitic diode is coupled to the second source electrode and a second cathode of the second parasitic diode is coupled to the second drain electrode, and
wherein the back surface of the first semiconductor chip and the back surface of the second semiconductor chip are faced to each other such that the first drain electrode and the second drain electrode are in contact with each other via a conductive member.

2. The semiconductor device according to claim 1, wherein the conductive member is a conductive tape.

3. The semiconductor device according to claim 1, wherein the conductive member includes:
a lead frame provided between the first drain electrode and the second drain electrode;
a first conductive paste adhered to the first drain electrode and the lead frame; and
a second conductive paste adhered to the second drain electrode and the lead frame.

4. The semiconductor device according to claim 1 further comprising:
a third semiconductor chip including a control circuit electrically connected to the first gate wiring and the second gate wiring,
wherein the control circuit has a function of supplying a gate potential to the first gate wiring and the second gate wiring in order to switch an ON state and an OFF state of each of the first MOSFET and the second MOSFET.

5. The semiconductor device according to claim 1,
wherein the second semiconductor chip further includes:
a control circuit electrically connected to the first gate wiring and the second gate wiring, and
wherein the control circuit has a function of supplying a gate potential to the first gate wiring and the second gate wiring in order to switch an ON state and an OFF state of each of the first MOSFET and the second MOSFET.

6. The semiconductor device according to claim 1, wherein the first semiconductor chip includes:
an n-type first semiconductor substrate having a front surface and a back surface;
a p-type first body region formed in the first semiconductor substrate on a side of the front surface of the first semiconductor substrate;
an n-type first source region formed in the first body region;
a first trench formed in the first semiconductor substrate on the side of the front surface of the first semiconductor substrate such that a bottom portion thereof is located below the first body region;
a first gate insulating film formed inside the first trench;
a first gate electrode formed on the first gate insulating film so as to fill the inside of the first trench;
a first interlayer insulating film formed on the front surface of the first semiconductor substrate;
the first source electrode formed on the first interlayer insulating film and electrically connected to the first body region and the first source region;
the first gate wiring formed on the first interlayer insulating film and electrically connected to the first gate electrode;
an n-type first drain region formed in the first semiconductor substrate on a side of the back surface of the first semiconductor substrate; and
the first drain electrode formed on the back surface of the first semiconductor substrate and electrically connected to the first drain region, wherein the second semiconductor chip includes:
an n-type second semiconductor substrate having a front surface and a back surface;
a p-type second body region formed in the second semiconductor substrate on a side of the front surface of the second semiconductor substrate;
an n-type second source region formed in the second body region;
a second trench formed in the second semiconductor substrate on the side of the front surface of the second semiconductor substrate such that a bottom portion thereof is located below the second body region;
a second gate insulating film formed inside the second trench;
a second gate electrode formed on the second gate insulating film so as to fill the inside of the second trench;
a second interlayer insulating film formed on the front surface of the second semiconductor substrate;
the second source electrode formed on the second interlayer insulating film and electrically connected to the second body region and the second source region;
the second gate wiring formed on the second interlayer insulating film and electrically connected to the second gate electrode;
an n-type second drain region formed in the second semiconductor substrate on a side of the back surface of the second semiconductor substrate; and
the second drain electrode formed on the back surface of the second semiconductor substrate and electrically connected to the second drain region,
wherein the first parasitic diode is composed of the first body region and the first semiconductor substrate and the first drain region located below the first body region, and
wherein the second parasitic diode is composed of the second body region and the second semiconductor substrate and the second drain region located below the second body region.

7. The semiconductor device according to claim 6,
wherein the second semiconductor chip further includes:
a p-type column region formed in the second semiconductor substrate located below the second body region.

8. A circuit device using the semiconductor device according to claim 1 as a switch, comprising:
a battery having a positive electrode and a negative electrode; and
a load,
wherein the first source electrode is electrically connected to the positive electrode, and
wherein the second source electrode is electrically connected to the negative electrode via the load.
